(19) United States
(12) Patent Application Publication
(10) Pub. No.: US 2014/0042200 A1
(43) Pub. Date: Feb. 13, 2014

(54) Display Device

(71) Applicant: Ehsan Namani, London (GB)

(72) Inventor: Ehsan Namani, London (GB)

(21) Appl. No.: 13/625,320

(22) Filed: Sep. 24, 2012

(30) Foreign Application Priority Data
Aug. 10, 2012 (GB) 1214417.6

(51) Int. Cl. H05K 7/00; B60R 11/02

(52) U.S. Cl. CPC H05K 7/00; B60R 11/0235
USPC 224/413; 224/400; 224/433; 361/679.01

(57) ABSTRACT

According to the present invention there is provided a display device comprising in use a screen in a weatherproof cover and having: a frame accepting the screen, insertable in a scooter or motorbike carrier container, said container mounting on a vehicle, said vehicle typically with two or three wheels, and said display device including at least one lock mechanism.

### CROSS-REFERENCES TO RELATED APPLICATIONS

The present application claims priority from United Kingdom Application Serial Number 1214417.6 filed on Aug. 10, 2012, which is hereby incorporated herein by reference in its entirety.

### TECHNICAL FIELD

The present invention relates to a display device, more particularly a transportable display device typically but not exclusively for use on or with a two or three wheeled vehicle.

### BACKGROUND OF THE INVENTION

In Being able to advertise in all forms of media and in multiple locations is an essential part of business strategy to ensure success and in particular growth of an enterprise.

In spite of recessions, the outdoor media market is typically healthy. There is heavy demand for both the traditional poster medium and increasingly the growing number of ambient media delivery mechanisms. Digital screen media is now well established as a credible mainstream outdoor advertising platform with major advertisers taking advertising on screens both large and small in the outdoor environment.

Visual advertising such as posters, billboards and television adverts is popular and can engage a large number of users due to captive audiences, number of viewings and placement possibilities in front of users. Strategic placement of such advertising can also target certain groups for example, placing a food advert in the break of a cookery program.

Poster and billboard advertising in particular can be a cost effective way to reach users who may be caught in traffic however the posters typically need changing on a regular basis due to conditions, and may unsuitable for changing advertising needs such as weekly or daily offers.

Electronic advertising billboards have been introduced in major cities, however can be costly, particularly for smaller businesses to apply for advertising, so is not widely available or suitable.

### PRIOR ART

Accordingly a number of patent applications have been filed in an attempt to resolve the problem or similar, including the following:

Granted U.S. Pat. No. 7,936,564 (BROWN) discloses a mobile display apparatus, comprising: a first structure for attaching the display apparatus to a mobile structure; at least one display module coupled the first structure to form a channel extending between the first structure and the at least one display module, the at least one display module positioned and configured to display at least a portion of an adaptable image; and a ventilation system in communication with the channel.

Granted U.S. Pat. No. 7,478,492 (MADONIA) discloses a display integrated with and mounted to an exterior portion of a motor vehicle, comprising: a flat panel display mounted flush to an exterior portion of a vehicle body; a control circuit coupled for controlling the flat panel display; a memory device coupled to the control circuit for storing images; and an operator control panel coupled to the control circuit for controlling operation of the flat panel display.

Granted U.S. Pat. No. 7,154,383 (BERQUIST) discloses a method of dynamically displaying advertising comprising: attaching a dynamic display apparatus to a vehicle; storing a plurality of advertising messages; displaying an advertising message via the display apparatus; and advancing advertising messages displayed based upon vehicle motion information.

In contrast the present invention provides a means reaching a maximum of potential advertising targets, in a dynamic, cost-effective and rapidly adaptable fashion.

### BRIEF SUMMARY OF EMBODIMENTS OF THE INVENTION

(1) The present invention relates to a container adapted to be located onto a vehicle exterior, and the container is adapted to receive a screen for external display.

(2) In a variant, the container includes a frame for receiving the screen.

(3) In another variant, the container has a rack adapted to slidably receive the screen.

(4) In a further variant, the container the vehicle is two or three wheeled comprising: a motorcycle, a moped, a rickshaw, a bicycle or a four wheeled motorcycle.

(5) In still another variant, the container has a mechanism to secure said screen into the frame container.

(6) In yet a further variant, the container has a screen adapted to be inserted into the container.

(7) In a variant, the container has a frame adapted to accept a screen and be inserted into the container.

(8) In another variant, the container has a displaceable flap capable of retaining a screen.

(9) In a further variant, the container has a frame container adapted to be slid into the rack of the container.

(10) In still another variant, the container has a frame container adapted to be slid into the rack of the container and including a resilient material, such as a shock resistant pad, resilient washers or flexible grommets located between the screen and container.

(11) In yet a further variant of the container, the washers or grommets are made of rubber.

(12) In a variant, a display system comprises any of the containers previously described.

(13) In another variant, a display system comprises any of the containers previously described, and has a frame container.

(14) In a further variant, a display system comprises any of the containers previously described, and has a connection mechanism so as to provide power to said screen from a vehicle battery.

(15) In still another variant, the display system is configured to power up upon switching of a vehicle's ignition and is provided with an additional electricity supply, adapted to charge the battery.

(16) In yet a further variant, the display system comprises an expandable length spiral cable connected to the vehicle battery.

(17) In a variant, the display system has a weather-proof cover for the screen.

(18) In another variant, the display system has a shock resistant padding inside the screen cover to protect the screen from damage.

(19) In still another variant, the display system is configured to be installed to back and sides of vehicles.

(20) In yet a further variant, a vehicle is equipped with any display system previously described.

Other features and aspects of the invention will become apparent from the following detailed description, taken in conjunction with the accompanying drawings, which illustrate, by way of example, the features in accordance with embodiments of the invention. The summary is not intended to limit the scope of the invention, which is defined solely by the claims attached hereto.

### BRIEF DESCRIPTION OF THE DRAWINGS

The present invention, in accordance with one or more various embodiments, is described in detail with reference to the following figures. The drawings are provided for purposes of illustration only and merely depict typical or example embodiments of the invention. These drawings are provided to facilitate the reader's understanding of the invention and shall not be considered limiting of the breadth, scope, or applicability of the invention. It should be noted that for clarity and ease of illustration these drawings are not necessarily made to scale.

Some of the figures included herein illustrate various embodiments of the invention from different viewing angles. Although the accompanying descriptive text may refer to such views as “top,” “bottom” or “side” views, such references are merely descriptive and do not imply or require that the invention be implemented or used in a particular spatial orientation unless explicitly stated otherwise.

FIGS. 1 to 6 show sketches of parts of an embodiment of the device of the present invention in post and pre-assembly;

FIGS. 7 and 8 show sketches of the embodiment of FIG. 1 in use; and

FIG. 9 illustrates the wiring of a circuit envisaged to be in use for preferred embodiments.

The figures are not intended to be exhaustive or to limit the invention to the precise form disclosed. It should be understood that the invention can be practiced with modification and alteration, and that the invention be limited only by the claims and the equivalents thereof.

### DETAILED DESCRIPTION OF THE EMBODIMENTS OF THE INVENTION

From time-to-time, the present invention is described herein in terms of example environments. Description in terms of these environments is provided to allow the various features and embodiments of the invention to be portrayed in the context of an exemplary application. After reading this description, it will become apparent to one of ordinary skill in the art how the invention can be implemented in different and alternative environments.

Unless defined otherwise, all technical and scientific terms used herein have the same meaning as is commonly understood by one of ordinary skill in the art to which this invention belongs. All patents, applications, published applications and other publications referred to herein are incorporated by reference in their entirety. If a definition set forth in this section is contrary to or otherwise inconsistent with a definition set forth in applications, published applications and other publications that are herein incorporated by reference, the definition set forth in this document prevails over the definition that is incorporated herein by reference.

The following reference numbers are used throughout this document:
Liquid crystal display (LCD) 1
Power cable 2
Locking mechanism 3
Hinge 4
4 cap nuts 5
4 screw washers 6
Securement bolts 7
Handle 8
Spiral or flexible power lead 9
Secondary battery 10
Scooter or motorbike carrier container 11
Displaceable flap 12
Screen cover 13
Screen 14
Lock slot 15
Padding 16
Frame or Rack 17

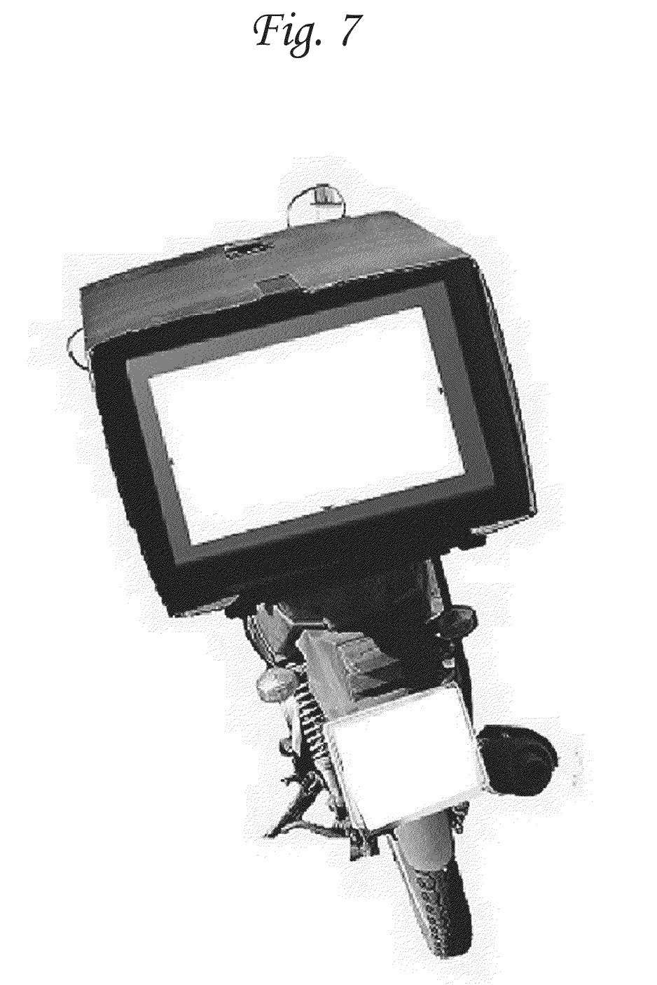

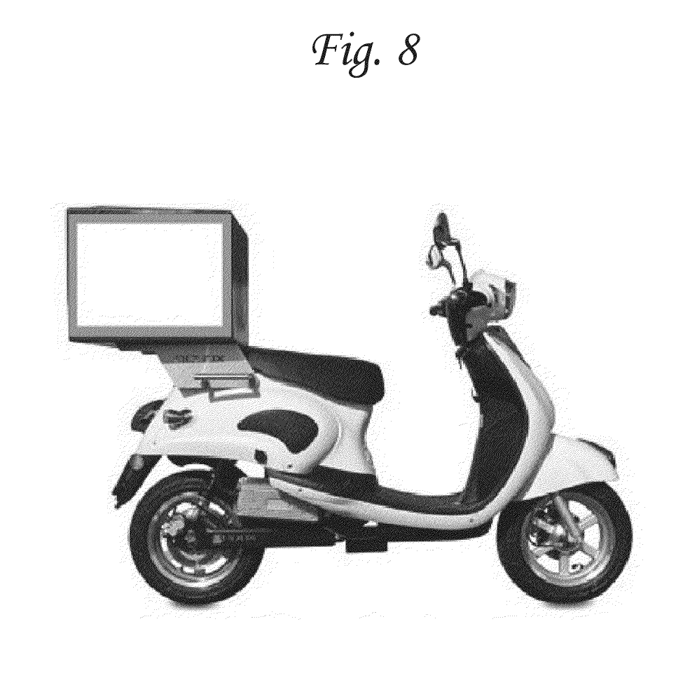

These parts are assembled by a user or come preassembled in order to provide device for mounting to a motorcycle as pictured in FIGS. 7 and 8.

Technical specifications of the screen may include as follows:

LCD screen: Size: 7″, 12″, 15″, 17″, 19″ up to A1, resolution: 1366×768

Compatible file formats that may be used on the screen include:

Picture formats: BMP/JPEG

Audio formats: MP3/WMA

Video formats: MPEG1(VCD), MPEG2(DVD), MPEG4

Compatible connections for the screen may include:

USB: high speed USB 2.0

RJ45

### Wi-Fi

3G Network

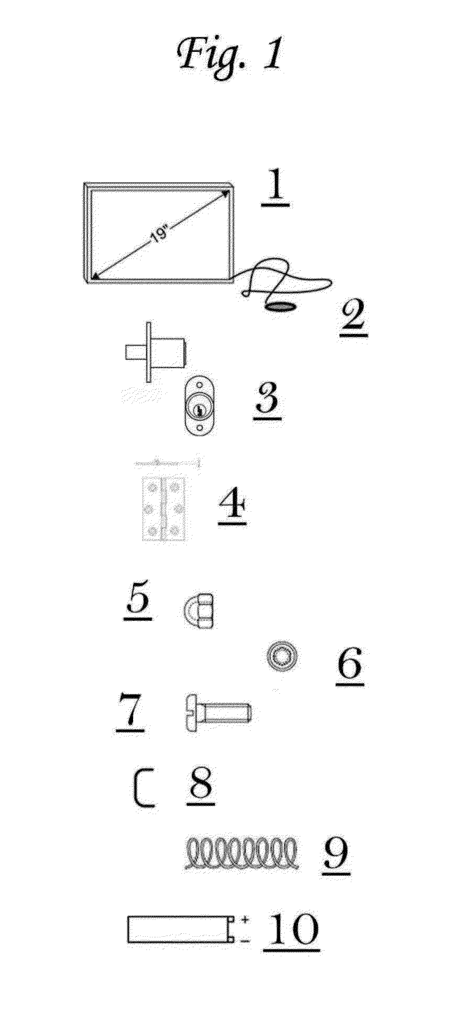

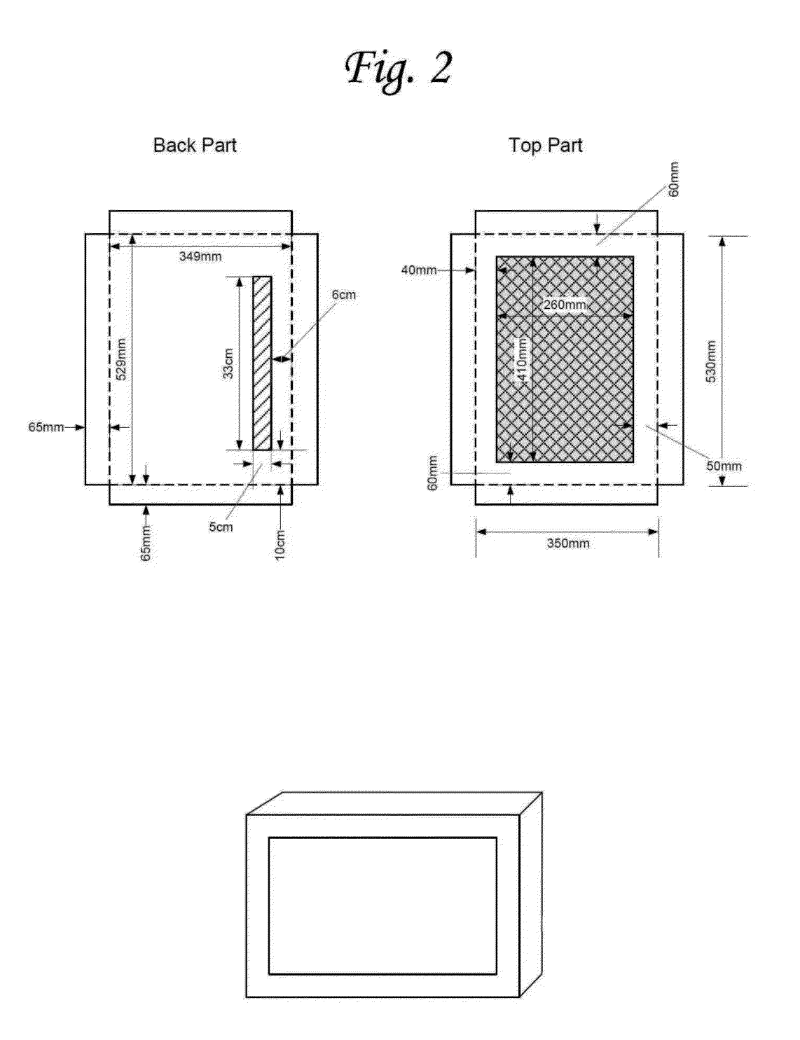

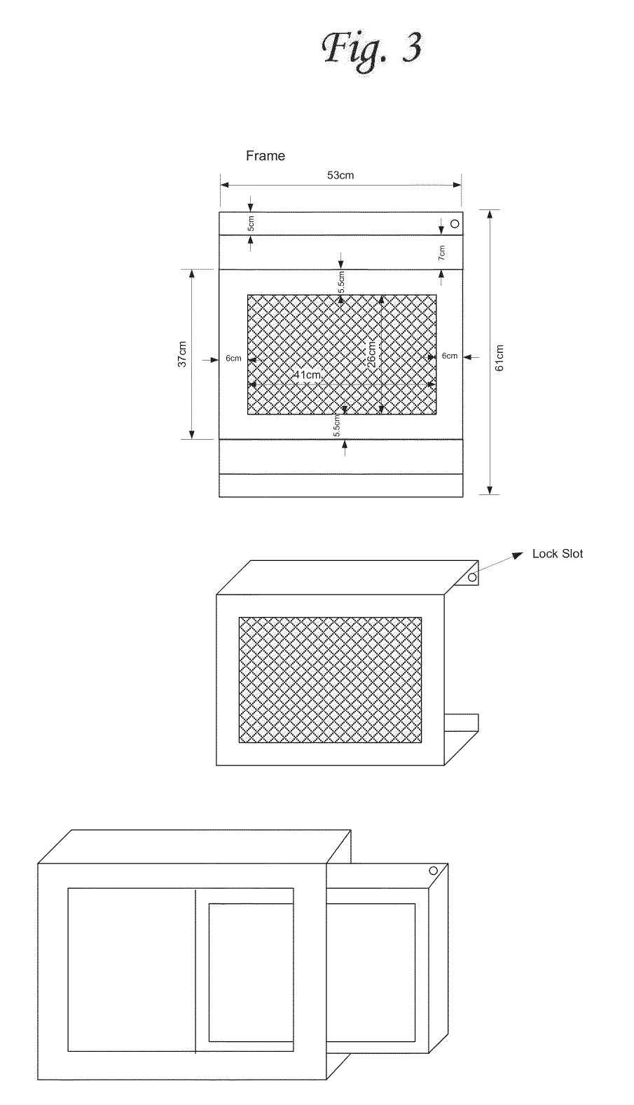

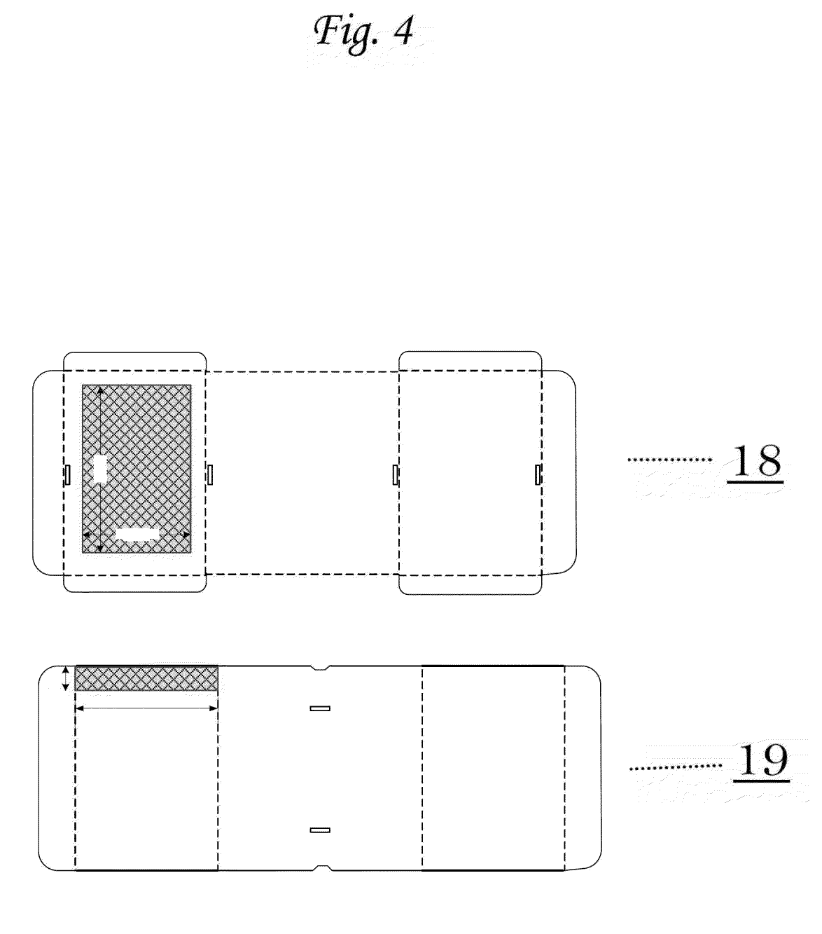

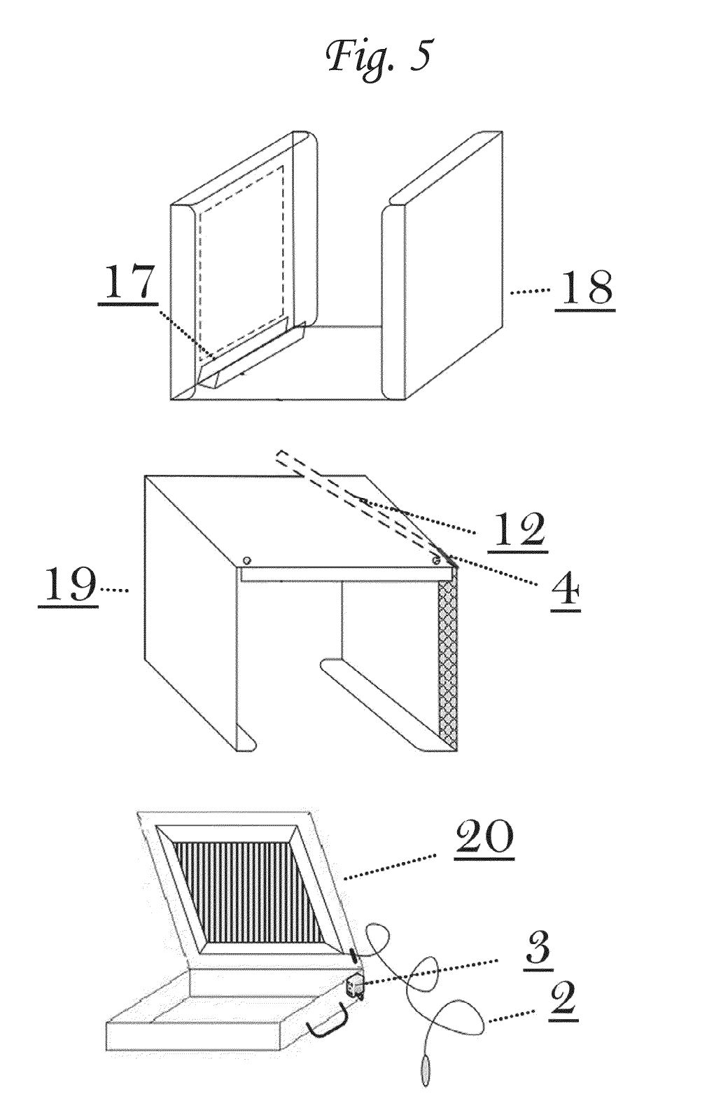

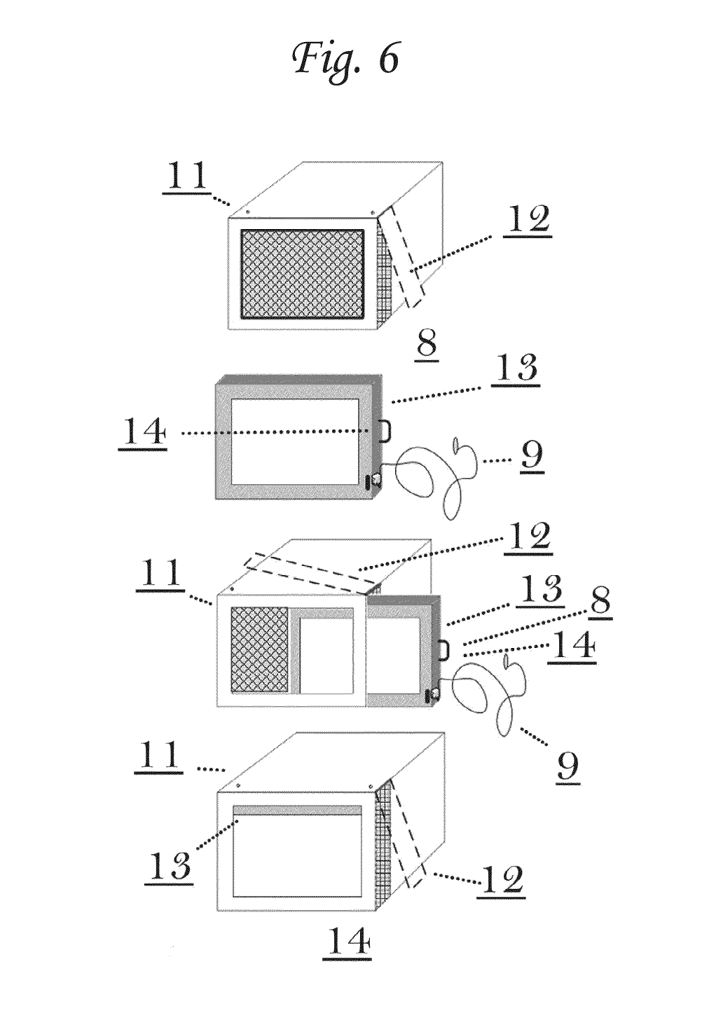

According to the present invention, referring to FIGS. 1-9, there is provided a display device comprising in use a screen in a weatherproof cover and having: a frame accepting the screen fitted on the back of a scooter and motorbike carrier container, said container mounting on a vehicle, said vehicle typically with two or three wheels, and said display device including at least one lock mechanism.

More particularly the present invention provides a display device comprising in use: a weatherproof screen or a screen in a weatherproof cover at least in part including transparent material screen holding apparatus and lock mechanism.

The at least one lock mechanism may be used for all of: locking the screen into the frame, locking the frame into the container and/or locking the container onto the vehicle. This may depend by embodiment on comparative expense and location of the frame or container.

The frame is typically installed inside a scooter or motorbike carrier container for, and typically situate in use towards a rearmost location or side location on a vehicle with two or three wheels, wherein the display screen is fastened or secured inside the frame and locked on its position; said container having a flap that displaces to accept or hold the frame or rack in embodiments where the rack is also displaceable. Furthermore the display device can be permanently fixed on or in a molded container.

In yet further embodiments the container may comprise of a jacket to clothe an existing container, said jacket being formed of flexible material that allows displacement, movement and/or deformation; and wherein the material in such embodiments may include insulative properties.

The display device in preferred embodiments therefore ideally provides a digital advertising screen facility located in or on the back of scooter carrier containers.

In some preferred embodiments the container may be formed of at least two main interlocking body parts that when interlocked form the container. It is envisaged that the container therefore is substantially formed by two U-shaped parts with connectors or tabs. In other embodiments the container may be a molded synthetic plastic whole. The container may have different sizes.

In some embodiments the parts are predominantly formed of a durable, lightweight rigid or semi rigid material such as synthetic plastic or aluminum panels. It is envisaged the material may include or be accompanied with material having insulating properties so as to assist in maintaining the temperature of transported items such as food. In some embodiments the parts may be formed in a flexible insulating material, such as formed by two fabric faces and a foam or aerated core.

In some further embodiments the container may be molded from a synthetic plastic or similar lightweight, durable material to form a solid structure that is not collapsible. In yet further embodiments the parts may surround, encapsulate or cover a separately provided container.

In all preferred embodiments at least one section of the container is or provides access to a hatch that can be opened in order to load and empty delivery goods contained within the container in use.

Typically said hatch may be hinged, sliding or otherwise displaceable and may include a locking mechanism so that the hatch may be securely closed when being transported or when left unattended. Typically in use the hatch is situate to fore of the container.

In all preferred embodiments the parts when interlocked or as assembled provide an inner cavity, which cavity is used to hold a screen and said cavity being provided with the frame or rack in some embodiments so that the screen may be slide into the container. Typically the cavity is formed by addition of a partition.

The cavity includes a frame, rack or cradle to support the screen. Typically the frame includes at least two channels in which the screen sits in and may slide out on, or provide the screen with support and allow its movement. Ideally it is envisaged the frame may include padding where the screen is liable to come into contact with the frame so as to minimize damage.

Typically the screen is fragile and prone to cracking and damage, if exposed to excessive impacts or vibration, shock-resistant padding may protect the screen from damage on the move. This padding or cushioning may be included inside the screen cover.

In further embodiments the screen is a flexible or electronic ink surface so as to allow movement, elasticity, and/or deformability such as a screen with thickness of a sheet of paper, flexible and conformal, said surface being printed or adhered to the container.

Preferably however the cavity is for accepting a screen which when in use is visible when viewing the container externally wherein one wall of the container includes a cutaway or transparent section to enable the screen to be visible.

In a preferred embodiment the cavity is watertight so that when closed there can be no water ingress, thus enabling the screen to operate even in damp, humid or wet conditions such as rain.

The cavity includes an opening to accept the screen which further includes a waterproof seal so that when closed the cavity is watertight. The opening may be a hinged door or detachable lid.

In other embodiments the cavity is not waterproof but instead the cavity accepts a screen that is adapted to be waterproof.

Typically the cavity will include an aperture, adaptor or connector for receiving a power supply or power supply lead. Said aperture preferably includes a seal such as an O-ring to provide a waterproof connection. The lead to the battery advantageously connects via male and female connectors within the cavity in order to allow separation of the connection when needed and minimizing weather or water ingress.

In some preferred embodiments, the lead or leads run to the battery permanently in order that for example connection may be simple clip, push or click fitting inside the container and wherein the screen may receive electric power automatically when ignition of the scooter is on.

When the scooter/motor vehicle ignition is switched off the wiring is ideally such that the screen continues to play, wherein a secondary independent backup battery activates to provide power to the screen. This enables the screen to be playing whilst the scooter/motor vehicle is stationary without any power from the Scooter/motor vehicle. Said secondary battery may be provided with trickle charging from the battery and/or vehicle alternator.

A spiral expandable cable is ideally used for some connection leads in order to be extendable and/or flexible when the display device or scooter carrier container is required to move or slide backward for example on runners allowing the user or other to access fuel fillers or otherwise so that the display device and/or container may be displaced for fueling, or any other movements to prevent any problems.

In another embodiment the container or the frame may have the ability to be tilted so as to angle the screen for preferential viewing, for example so the screen is at a suitable angle for a following vehicle to view. Typically this is facilitated by the addition of a wedge to the underside of the rack or container. Alternatively the container may include a frame that is adjustable.

In another embodiment the container may include a sunshade in the form of a projection that extends above the screen to shade the screen from direct sunlight.

It is envisaged that the screen has multi-functionality. Predominantly the screen can display advertising images and messages, but may also be Global Positioning System (GPS) enabled. GPS may be able to assist with directions but may also allow advertising to be tailored to an area, such as the shops in the region.

The screen may also be able to accept alternative media inputs such as a camera or computer and include memory storage so as to be able to hold multiple data.

The screen may include integrated controls means or may be remote controlled. It is also envisaged the screen may be able to receive and transmit by alternative means such as Bluetooth (Trade Mark), Wi-Fi (Trade Mark), radio frequency and other similar forms of wireless communication. This allows the user multiple means of access and control of the display device.

Preferably the display device can be removably attached to a surface so that it can be used on different surfaces and so that it can be removed when not in use or when not required. Most preferably to the display device is removably attached to rear of a delivery motorcycle.

It is envisaged that in preferred embodiments the device is lockably attached to the rear of a motorcycle, scooter or moped, so as to ensure it is secure during movement or transportation and for security.

The preferred embodiment of the display device thereby provides high impact, geographically targeted advertising messages. In particular the pictured embodiment is for use with scooters and motorcycles.

In preferred embodiments the locking mechanism provides at least one theft-protection device, to effectively prevent the player and any memory card from being stolen in public place and protect the power cord being pull out easily.

The device may consequently include clamps that can be connected to the motorcycle. Alternatively a bracket may be used to attach the display device to the motorcycle.

Ideally the screen includes a timer function: to allow the player to power on/off automatically at defined times. Further embodiments include auto-standby and sleep mode and built-in global positioning system software (GPS) to track position on the road and target advertising accordingly.

The screen ideally also includes further electronic apparatus and the preferred embodiment of the screen includes built-in memory, memory card upgrade facility, universal serial bus (USB) connectivity, RJ45 connector, mobile telephony and wireless internet connectivity and enables a user to play video and digital photos.

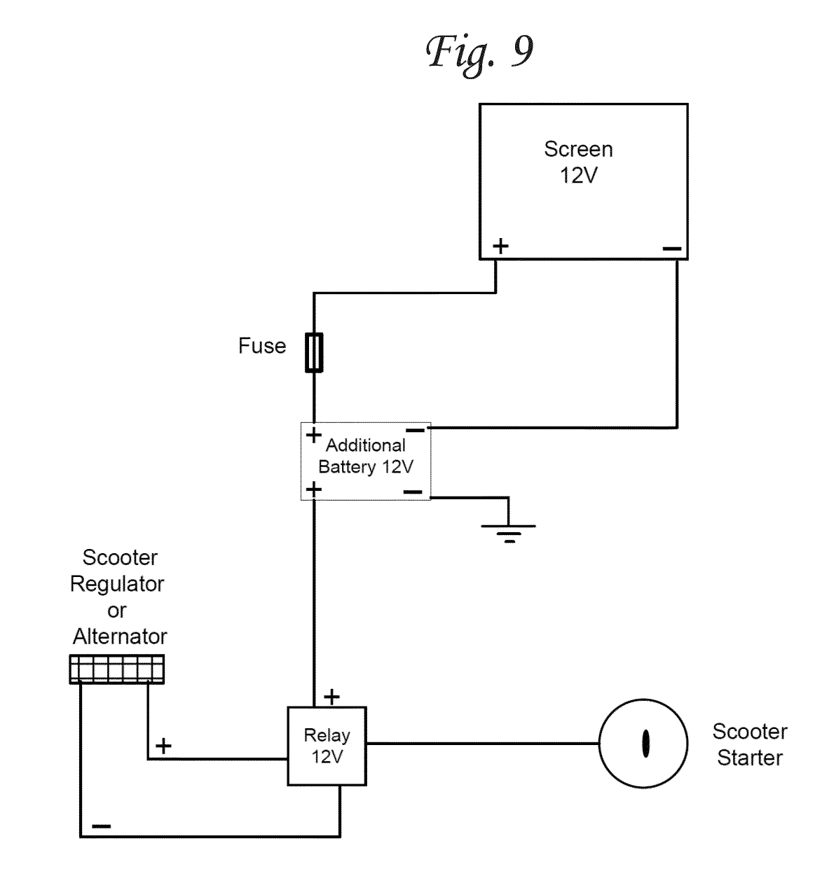

In a variant, referring to FIG. 9, a wiring diagram illustrates the screen is only ON when the scooter starts and is operating, and the screen is shut down when the scooter is switched off.

In another variant, referring to FIG. 9, a wire diagram illustrates that the screen will be on continuously ON even when the scooter is OFF, as long as the additional battery is charged. By starting the scooter, the regulator will recharge the additional battery and when it is switched OFF the screen will run from the additional battery until it is empty.

While various embodiments of the present invention have been described above, it should be understood that they have been presented by way of example only, and not of limitation. Likewise, the various diagrams may depict an example architectural or other configuration for the invention, which is done to aid in understanding the features and functionality that can be included in the invention. The invention is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the present invention. Also, a multitude of different constituent module names other than those depicted herein can be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Although the invention is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the invention, whether or not such embodiments are described and whether or not such features are presented as being a part of a described embodiment. Thus the breadth and scope of the present invention should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

A group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise. Furthermore, although items, elements or components of the invention may be described or claimed in the singular, the plural is contemplated to be within the scope thereof unless limitation to the singular is explicitly stated.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed across multiple locations.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

What is claimed is:

1. A container adapted to be located onto a vehicle exterior, said container being adapted to receive a screen for external display.

2. The container of claim 1, wherein the container includes a frame for receiving the screen.

3. The container of claim 2, further comprising a rack adapted to slidably receive the screen.

4. The container of claim 3, wherein the vehicle is two or three wheeled comprising: a motorcycle, a moped, a rickshaw, a bicycle or a four wheeled motorcycle.

5. The container of claim 4, further comprising a mechanism to secure said screen into the frame container.

6. The container of claim 5, further comprising a screen adapted to be inserted into the container.

7. The container of claim 5, further comprising a frame adapted to accept a screen and be inserted into the container.

8. The container of claim 5, further comprising a displaceable flap capable of retaining a screen.

9. The container of claim 3, further comprising a frame container adapted to be slid into the rack of the container.

10. The container of claim 5, further comprising a frame container adapted to be slid into the rack of the container and including a resilient material, such as a shock resistant pad, resilient washers or flexible grommets located between the screen and container.

11. The container of claim 10, wherein the washers or grommets are made of rubber.

12. A display system comprising the container of claim 6.

13. A display system comprising the container of claim 12, further comprising a frame container.

14. A display system comprising the container of claim 12, further comprising a connection mechanism so as to provide power to said screen from a vehicle battery.

15. The display system of claim 14, configured to power up upon switching of a vehicle's ignition and is provided with an additional electricity supply, adapted to charge the battery.

16. The display system of claim 15, further comprising an expandable length spiral cable connected to the vehicle battery.

17. The display system of claim 15, further comprising a weather-proof cover for the screen.

18. The display system of claim 17, further comprising a shock resistant padding inside the screen cover to protect the screen from damage.

19. The display system of claim 18, wherein the system is configured to be installed to back and sides of vehicles.

20. A vehicle equipped with a display system according to claim 12.
